(19) United States
(12) Patent Application Publication
(10) Pub. No.: US 2026/0223390 A1
(43) Pub. Date: Jul. 30, 2026

(54) SIC MOSFET WITH IMPROVED HIGH CURRENT ON-RESISTANCE PERFORMANCE

(71) Applicant: Renesas Electronics Corporation, Tokyo (JP)

(72) Inventors: Meng Chia LEE, Dallas, TX (US); Kijeong HAN, Morrisville, NC (US); Dilip Madhav RISBUD, San Jose, CA (US)

(73) Assignee: Renesas Electronics Corporation, Tokyo (JP)

(21) Appl. No.: 19/039,945

(22) Filed: Jan. 29, 2025

(51) Int. Cl. H10D 30/66; H10D 30/01; H10D 62/13; H10D 62/832; H10D 62/834; H10D 64/62

(52) U.S. Cl. CPC H10D 30/66; H10D 30/0293; H10D 62/153; H10D 62/154; H10D 62/8325; H10D 62/834; H10D 64/62

(57) ABSTRACT

A method of forming a semiconductor structure includes forming a silicon carbide semiconductor substrate of a first conductivity type. A drift layer of the first conductivity type is formed above an upper surface of the semiconductor substrate. A junction field-effect transistor (JFET) region of the first conductivity type is formed above the drift layer with base regions of a second conductivity type positioned on opposite sides of a top portion of the JFET region. Each base region contacts a bottom portion of the JFET region. A hard mask is formed above the top portion of the JFET region located between the base regions. First doped regions of the first conductivity type are formed within the JFET region, at an interface between the base regions and the JFET region, extending into the JFET region such that the first doped regions reduce a width of the top portion of the JFET region.

### BACKGROUND

The present disclosure generally relates to the field of semiconductor devices, and more particularly to silicon carbide metal-oxide-semiconductor field-effect transistors.

The rapid advancement of power electronics has created a growing demand for high-performance semiconductor devices capable of operating at elevated voltages, temperatures, and frequencies. Metal-oxide-semiconductor field-effect transistors (MOSFETs) are integral components in modern power conversion and management systems, used in a wide range of applications, including electric vehicles, renewable energy systems, and industrial motor drives. Among the various semiconductor materials, silicon carbide (SiC) has gained significant attention due to its superior properties, such as a wide bandgap, high thermal conductivity, and excellent electric field breakdown strength. These characteristics make SiC an ideal candidate for high-voltage and high-temperature applications, outperforming traditional silicon-based devices in terms of efficiency and thermal performance.

SiC MOSFETs offer notable advantages, including high voltage tolerance, high-temperature performance, and reduced switching losses. However, as device designs evolve to meet the increasing demand for enhanced performance and reduced size, challenges persist in maintaining optimal on-resistance (Ron) at high current densities. The ability to minimize Ron, which directly impacts power loss and thermal dissipation, remains a critical factor in ensuring the overall efficiency of SiC MOSFETs in high-power applications.

### SUMMARY

According to an embodiment of the present disclosure, a method of forming a semiconductor structure includes forming a semiconductor substrate of a first conductivity type, the semiconductor substrate including a silicon carbide substrate, forming a drift layer of the first conductivity type above an upper surface of the semiconductor substrate, forming a junction field-effect transistor (JFET) region of the first conductivity type above the drift layer, forming base regions of a second conductivity type on opposite sides of a top portion of the JFET region, each base region is formed above and in contact with a bottom portion of the JFET region, with the second conductivity type being opposite to the first conductivity type, forming a hard mask above the top portion of the JFET region located between the base regions, and forming first doped regions of the first conductivity type within the JFET region, each first doped region being positioned at an interface between the base regions and the JFET region, the first doped regions extending into the JFET region such that a width of the top portion of the JFET region is reduced by the first doped regions.

According to another embodiment of the present disclosure, a method of forming a semiconductor structure includes forming a semiconductor substrate of a first conductivity type, the semiconductor substrate including a silicon carbide substrate, forming a drift layer of the first conductivity type above an upper surface of the semiconductor substrate, forming a JFET region of the first conductivity type above the drift layer, forming base regions of a second conductivity type on opposite sides of a top portion of the JFET region, each base region being formed above and in contact with a bottom portion of the JFET region, with the second conductivity type being opposite to the first conductivity type, forming a hard mask above the top portion of the JFET region located between the base regions, and conducting a localized tilted ion implantation on the JFET region to implant nitrogen ions, with the localized implantation forming first doped regions of the first conductivity type within the JFET region, the first doped regions being formed at an interface between the base regions and the JFET region, the first doped regions extending into the JFET region such that a width of the top portion of the JFET region is reduced by the first doped regions.

According to yet another embodiment of the present disclosure, a semiconductor structure includes a semiconductor substrate of a first conductivity type, the semiconductor substrate including a silicon carbide substrate, a drift layer of the first conductivity type disposed above an upper surface of the semiconductor substrate, a JFET region including a top portion and a bottom portion, the JFET region being disposed above the drift layer, a pair of base regions disposed on opposite sides of the top portion of the JFET region, a pair of first doped regions located at an interface between the base regions and the JFET region, the pair of first doped regions extending into the top portion of the JFET region such that a width of the top portion of the JFET region is reduced by the pair of first doped regions, and a pair of second doped regions located on a bottom portion of the base regions adjacent to the pair of first doped regions.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a cross-sectional view of a portion of a semiconductor structure at an intermediate stage of a semiconductor fabrication process, according to an embodiment of the present disclosure;

FIG. 2 is a cross-sectional view of the semiconductor structure illustrating a tilted implantation process used to form first doped regions, according to an embodiment of the present disclosure;

FIG. 3 is a cross-sectional view of the semiconductor structure illustrating forming sidewall spacers along a hard mask and forming second doped regions, according to an embodiment of the present disclosure;

FIG. 4 is a cross-sectional view of the semiconductor structure illustrating forming source regions, according to an embodiment of the present disclosure;

FIG. 5 is a cross-sectional view of the semiconductor structure illustrating forming a gate oxide, according to an embodiment of the present disclosure;

FIG. 6 is a cross-sectional view of the semiconductor structure illustrating forming a gate electrode, an interlevel dielectric layer and a top electrode, according to an embodiment of the present disclosure; and

FIG. 7 is a flowchart depicting operational steps for the fabrication of the semiconductor structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

SiC MOSFETs are widely used in high-power applications due to their superior efficiency, high-temperature performance, and robust current handling. However, as the cell pitch of SiC MOSFETs is reduced to improve device density and performance, the on-resistance (Ron) tends to degrade at higher current levels, primarily due to junction field-effect transistor (JFET) region pitching. This degradation is especially noticeable at elevated current densities, where current spreading becomes less effective, leading to increased Ron and reduced device performance. Furthermore, the temperature coefficient of Ron (Ron tempco) worsens when shrinking the cell pitch, mainly because the channel resistance (Rch) is more significantly affected than the resistance of the JFET region (RJFET). As a result, achieving low Ron at high current levels while maintaining favorable thermal characteristics becomes increasingly difficult, limiting the overall performance and reliability of the device.

Therefore, embodiments of the present disclosure provide a localized ion implantation of the JFET region that enhances current spreading at high current densities, thereby improving the on-resistance (Ron) performance in SiC MOSFETs. More particularly, embodiments of the present disclosure provide a method to selectively modify the JFET region without requiring additional photomasks that reduces the complexity and cost of fabrication. By narrowing the JFET region in a controlled manner, embodiments of the present disclosure can minimize the penalty on Ron temperature coefficient (Ron tempco) when reducing the cell pitch. This may result in a significant reduction in Ron degradation at high currents, while simultaneously maintaining favorable thermal stability and current spreading. Additionally, the proposed tilted implant design improves the overall efficiency of the device by ensuring better current conduction, which is crucial for high-power applications. Thus, this approach enables better overall performance of SiC MOSFETs with high current handling capabilities, even when the device pitch is reduced.

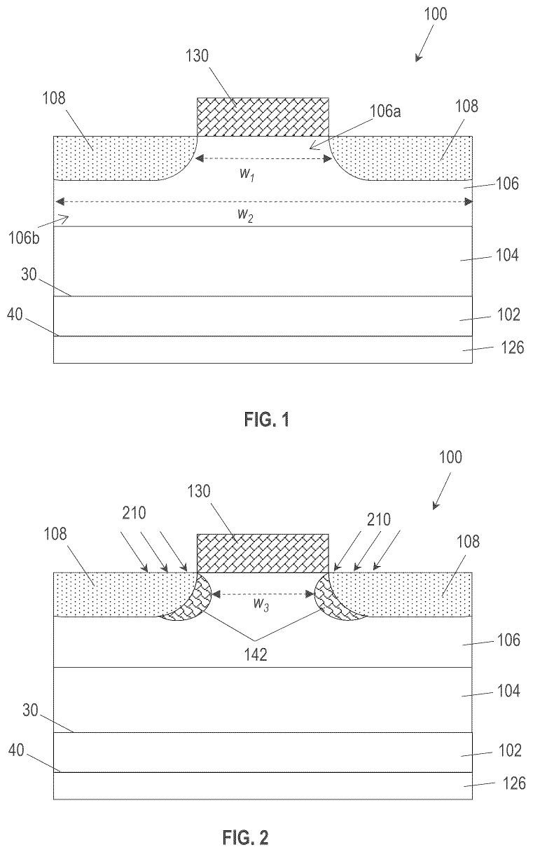

Embodiments by which the localized JFET implant for improved high current Ron in SiC MOSFETs can be implemented is described in detail below by referring to the accompanying drawings in FIGS. 1-7.

FIG. 1 is a cross-sectional view of a portion of a semiconductor structure 100 at an intermediate stage of a semiconductor fabrication process, according to an embodiment of the present disclosure. In this embodiment, semiconductor structure 100 represents a SiC planar MOSFET structure.

As depicted in the figure, semiconductor structure 100 can include a semiconductor substrate (hereinafter “substrate”) 102 of a first conductivity type that is made of silicon carbide (SiC). A thickness of the initial substrate 102 can be approximately 350 μm. The substrate 102 can be grinded to approximately 100 μm during backside processing steps. The impurity concentration in the substrate 102 can vary between approximately 1×10¹⁸ cm⁻³ to approximately 1×10¹⁹ cm⁻³. The first conductivity type can be P-type or N-type. In the depicted embodiment, the first conductivity type is N-type.

It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties. Substrate 102 further includes an upper surface 30 and a bottom surface 40.

A bottom metal layer 126 can be formed on the bottom surface 40 of the substrate 102. The bottom metal layer 126 serves as a drain terminal or drain electrode that provides electrical (ohmic) contact with substrate 102.

A drift layer 104 of the first conductivity type can be formed on the upper surface 30 of the substrate 102. The drift layer 104 is made of silicon carbide with an added impurity concentration that is lower than the impurity concentration of substrate 102. Drift layer 104 can be a region where carriers (e.g., electrons or holes) can drift from a source region (e.g., source region 110 in FIG. 4) to the drain region or substrate 102. In general, drift layer 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift layer 104 can be formed by chemical vapor deposition (CVD) of the semiconductor material (i.e., SiC).

A thickness of the drift layer 104 can be determined by the device voltage rating. For example, the thickness of the drift layer 104 can be approximately 10 μm for 1.2 kV rated devices. The impurity concentration of the drift layer 104 can be approximately 1×10¹⁶ cm⁻³ for 1.2 kV rated devices. However, the impurity concentration of the drift layer 104 is not limited to this value and may be in a range of approximately 1×10¹⁴ cm⁻³ to approximately 1×10¹⁷ cm⁻³ depending on the device voltage rating.

A JFET region 106 can be formed above and in contact with the drift layer 104. In some instances, JFET region 106 can be formed with a higher donor doping of the first conductivity type that can vary between approximately 1×10¹⁵ cm⁻³ and approximately 1×10¹⁸ cm⁻³. A (vertical) thickness of the JFET region 106 can be approximately 0.1 μm to approximately 3.5 μm. In an embodiment, JFET region 106 may include a top portion 106a and a bottom portion 106b. The top portion 106a of JFET region 106 may have a first (horizontal) width w₁ varying between approximately 0.3 μm to approximately 0.7 μm, while the bottom portion 106b of JFET region 106 may have a second (horizontal) width w₂ varying between approximately 1.5 μm to approximately 6 μm.

A base region 108, including a doped semiconductor region of a second conductivity type, can be formed on each side of the top portion 106a of JFET region 106, and above and in contact with the bottom portion 106b of JFET region 106. A thickness of the base regions 108 can be approximately 0.1 μm to approximately 1.0 μm. The impurity concentration of the base regions 108 can vary between approximately 1×10¹⁹ cm⁻³ to approximately 1×10²¹ cm⁻³. The second conductivity type can be P-type or N-type. Generally, the second conductivity type is opposite to the first conductivity type. Thus, in the depicted embodiment, the second conductivity type is P-type.

In one or more embodiments, varying impurity or dopant concentrations across the different regions of semiconductor structure 100 can be attained through ion implantation or the diffusion of impurity ions or dopants. For example, in embodiments in which the first conductivity type is N-type and the second conductivity type is P-type, N-type dopants such as phosphorus (P) or arsenic (As) can be implanted into different regions of semiconductor structure 100 to form N-type doped semiconductor regions, while P-type dopants such as boron (B), aluminum (Al) or gallium (Ga) can be implanted into different regions of semiconductor structure 100 to form the P-type doped semiconductor layers.

With continued reference to FIG. 1, a hard mask 130 is formed above an upper surface of top portion 106a of the JFET region 106, which is located between base regions 108. The hard mask 130 can be used to protect specific areas of the semiconductor structure 100 from being implanted during a subsequent implantation process. In one embodiment, hard mask 130 is made of silicon nitride (SiN), although other similar materials may also be considered. A thickness of the hard mask 130 can vary from approximately 100 nm to approximately 5000 nm.

FIG. 2 is a cross-sectional view of the semiconductor structure 100 illustrating a tilted implantation process 210 used to form first doped regions 142 within JFET region 106, according to an embodiment of the present disclosure. It should be noted that the description of FIG. 2 can refer to components shown in FIG. 1.

The tilted implantation process 210 includes an ion implantation process of the first conductivity type conducted on the semiconductor structure 100 to form first doped regions 142 within JFET region 106. In an embodiment in which the first conductivity type is N-type, the tilted implantation process 210 introduces nitrogen (N) ions at an angle to modify the doping profile within JFET region 106. It should be noted that although nitrogen is typically an acceptor in semiconductor materials like silicon (Si), in materials like SiC or other wide-bandgap semiconductors, nitrogen implantation generally results in N-type doping, as it contributes extra electrons to the material's conduction band. Thus, nitrogen implantation may be favored in SiC MOSFETs due to its excellent donor properties, compatibility with SiC's wide bandgap, low compensation tendencies, ease of implantation, and low diffusion characteristics.

In an exemplary embodiment, nitrogen ions can be implanted at a tilt angle of approximately 45 degrees, targeting an area of the JFET region 106 proximate to base regions 108. As a result, a first doped region 142 can be formed at an interface between each base region 108 and the JFET region 106, as depicted in the figure. Formation of first doped regions 142 enables controlled narrowing of the top portion 106a of the JFET region 106 located between base regions 108. This controlled narrowing can help minimize the penalty on the on-resistance temperature coefficient (Ron tempco) when reducing the cell pitch. In one embodiment, the first doped regions 142 can reduce the width of the top portion 106a of JFET region 106 from the first width w₁ to a third width w₃ of approximately 0.2 mm. As a result, first doped regions 142 can narrow the top portion 106a of the JFET region 106, located between base regions 108, by approximately 20%. The impurity concentration of the first doped regions 142 can vary from approximately 1×10¹⁵ cm⁻³ to Approximately 1×10¹⁸ cm⁻³.

In an embodiment, forming the first doped regions 142 may enable localized charge balance, which supports a higher local JFET dose without negatively impacting performance. Since current may primarily flow through regions with higher JFET doping (i.e., first doped regions 142), there may be less resistance penalty (Rsp) when reducing the size of the JFET region 106. Furthermore, the process may eliminate the need for additional masks, streamlining the fabrication steps and reducing complexity.

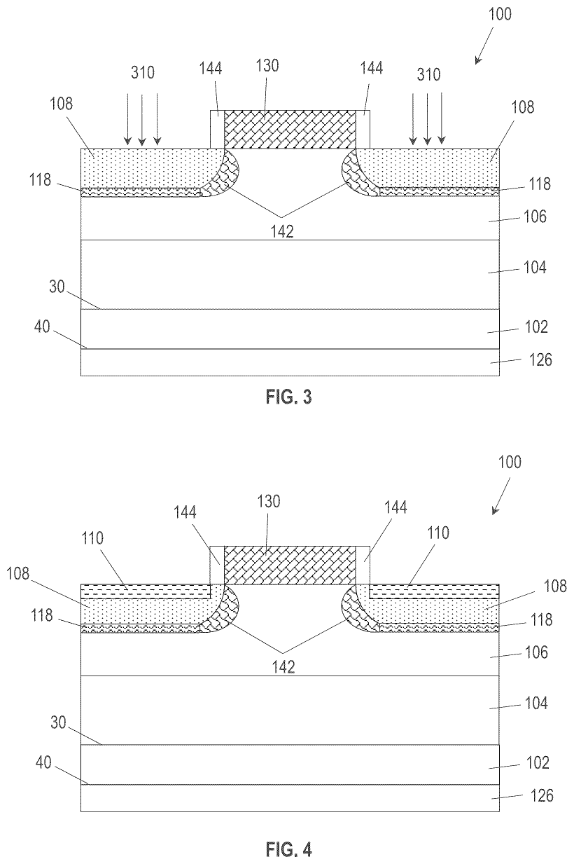

FIG. 3 is a cross-sectional view of the semiconductor structure 100 illustrating forming sidewall spacers 144 along hard mask 130 and second doped regions 118, according to an embodiment of the present disclosure. It should be noted that the description of FIG. 3 can refer to components shown in FIG. 1 and FIG. 2.

In the depicted embodiment, sidewall spacers 144 can be formed along opposite sides of the hard mask 130. The process of forming sidewall spacers 144 typically includes depositing a layer of an insulating material (e.g., SiN, SiO₂, and the like) above upper surfaces of the semiconductor structure 100 using deposition processes such as chemical vapor deposition (CVD) or plasma-enhanced chemical vapor deposition (PECVD). After deposition, a photoresist layer (not shown) can be applied, and photolithography is used to define areas where the insulating spacer material is not required. The photoresist layer is exposed to light through a mask, and then developed to leave exposed regions for etching. Etching is then carried out to remove the spacer material from areas of the semiconductor structure 100 where it is not needed, leaving the spacer material only along the sidewalls of the hard mask 130, as depicted in FIG. 3. In an embodiment, a (horizontal) thickness of the sidewall spacers may vary between approximately 0.1 mm to approximately 1 mm. The thickness of the sidewall spacers 144 can be controlled to ensure that a subsequent implantation process can effectively target specific areas of the semiconductor structure 100.

After forming sidewall spacers 144, an ion implantation process 310 can be conducted on the semiconductor structure 100 to form second doped regions 118. In this embodiment, the ion implantation process 310, can be a vertical or perpendicular implantation process (not tilted). Second doped regions 118 are composed of a heavily-doped silicon carbide layer of the second conductivity type. Second doped regions 118 can be formed with an impurity concentration of the second conductivity type varying between approximately 1×10¹⁹ cm⁻³ and approximately 1×10²¹ cm⁻³. In embodiments in which the second conductivity type is P-type, P-type dopants (such as boron) are implanted into the regions of the semiconductor structure 100 not covered by the sidewall spacers 144. Particularly, P-type dopants can be accelerated and directed towards the semiconductor structure 100 at a controlled energy level, ensuring that the implanted ions can penetrate deep into the material. The implantation energy is chosen to achieve a deeply-doped region that extends to the desired depth beneath the surface. This selective doping step creates the second doped region 118 of the second conductivity type on a bottom surface of each of the base regions 108. The second doped region 118 is positioned adjacent to the first doped regions 142. In a vertical direction, second doped regions 118 are disposed between base regions 108 and the bottom portion 106b of the JFET region 106. In embodiments in which the second conductivity type is P-type, the second doped region 118 can be referred to as a deeply-doped P-type region or DeepP region. A thickness of the second doped regions 118 can vary between approximately 0.1 μm and approximately 3.5 μm. In one or more embodiments after forming the second doped regions 118, the implanted region can be annealed to activate the dopants and repair any crystal damage.

FIG. 4 is a cross-sectional view of the semiconductor structure 100 illustrating forming source regions 110, according to an embodiment of the present disclosure. It should be noted that the description of FIG. 4 can refer to components shown in FIG. 1, FIG. 2, and FIG. 3.

Source regions 110 can be formed above and in contact with base regions 108. Source regions 110 can be formed adjacent to sidewall spacers 144, as depicted in the figure. A thickness of the source regions 110 is approximately 0.1 μm to approximately 0.5 μm. Source regions 110 may include a heavily-doped semiconductor layer of the first conductivity type. A dopant concentration of source regions 110 can vary, for example, between 1×10¹⁹ cm⁻³ and 1×10²¹ cm⁻³. After forming source regions 110, hard mask 130 and sidewalls spacers 144 can be selectively removed from the semiconductor structure 100 using any suitable dry or wet etching technique.

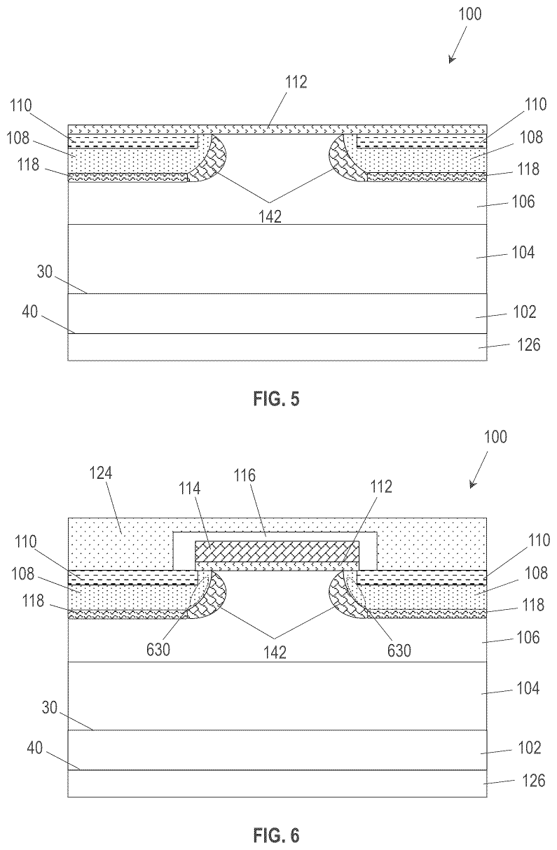

FIG. 5 is a cross-sectional view of the semiconductor structure 100 illustrating forming a gate oxide 112, according to an embodiment of the present disclosure. It should be noted that the description of FIG. 5 can refer to components shown in FIG. 1, FIG. 2, FIG. 3, and FIG. 4.

Gate oxide 112 can be formed above source regions 110, base regions 108 and JFET region 106 using various types of deposition processes. The gate oxide 112 can electrically separate a subsequently formed gate electrode 114 from active areas of the semiconductor structure 100. In one or more embodiments, gate oxide 112 can be formed by conformal deposition of a gate insulating film. Non-limiting examples of gate insulating films to form gate oxide 112 can include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO₂) and the like. In an exemplary embodiment, a thickness of the gate oxide 112 can vary between approximately 10 nm to approximately 100 nm.

FIG. 6 is a cross-sectional view of the semiconductor structure 100 illustrating forming a gate electrode 114, an interlevel dielectric layer 116 and a top metal layer 124, according to an embodiment of the present disclosure. It should be noted that the description of FIG. 6 can refer to components shown in FIG. 1, FIG. 2, FIG. 3, FIG. 4, and FIG. 5.

The process of forming gate electrode 114 usually includes depositing a conductive material, such as polysilicon, above the gate oxide 112. The gate electrode 114 and gate oxide 112 provide a gate structure for the semiconductor structure 100. It should be noted that the gate oxide 112 is removed from an upper surface of source regions 110 prior to forming the gate electrode 114. In one or more embodiments, a channel region 630 of the second conductivity type is formed within portions of base region 108 located below gate electrode 114 and adjacent to source regions 110, as depicted in the figure. Channel region 630 is formed proximate the first doped region 142 within JFET region 106.

After forming the gate electrode 114, interlevel dielectric layer 116 can be formed to fill voids and electrically isolate active regions within the semiconductor structure 100. The interlevel dielectric layer 116 is disposed above the gate electrode 114. More particularly, the interlevel dielectric layer 116 covers an upper surface and opposite sidewalls of gate electrode 114, opposite sidewalls of gate oxide 112, and partially covers an upper surface of source region 110. In one or more embodiments, the interlevel dielectric layer 116 can be formed by, for example, conformal deposition (e.g., CVD) of a dielectric material such as silicon oxide, silicon nitride, and the like. In one or more embodiments, a patterning process can be conducted on the interlevel dielectric layer 116 to achieved the shape shown in the figures.

Top metal layer 124 can be deposited above the interlevel dielectric layer 116 and above exposed portions of source regions 110. The top metal layer 124 provides a source terminal or source electrode (ohmic contact) that electrically contacts source regions 110.

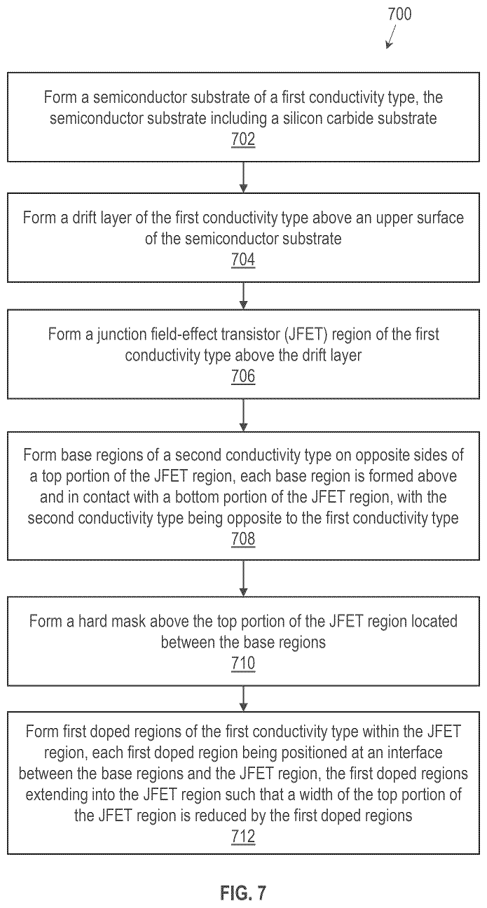

FIG. 7 is a flowchart 700 depicting operational steps for the fabrication of the semiconductor structure 100, according to an embodiment of the present disclosure. It should be noted that the description of FIG. 7 can refer to components shown in FIG. 1, FIG. 2, FIG. 3, FIG. 4, FIG. 5, and FIG. 6.

The process starts at step 702 by forming a semiconductor substrate of a first conductivity type. In an embodiment, the semiconductor substrate includes a silicon carbide substrate. The process continues at step 704 by forming a drift layer of the first conductivity type above an upper surface of the semiconductor substrate. The process continues at step 706 by forming a JFET region of the first conductivity type above the drift layer. The process continues at step 708 by forming base regions of a second conductivity type on opposite sides of a top portion of the JFET region. Each base region is formed above and in contact with a bottom portion of the JFET region. In an embodiment, the second conductivity type is opposite to the first conductivity type. The process continues at step 710 by forming a hard mask above the top portion of the JFET region located between the base regions.

The process continues at step 708 by forming first doped regions of the first conductivity type within the JFET region. Each first doped region is positioned at an interface between the base regions and the JFET region. The first doped regions extend into the JFET region such that a width of the top portion of the JFET region is reduced by the first doped regions. In an embodiment, forming the first doped regions includes conducting a tilted ion implantation on the JFET region to implant first type dopants of the first conductivity type. In an embodiment, the first type dopants include nitrogen. In an embodiment, a dopant concentration of the first type dopants is more than 1×10¹⁵ cm⁻³ and less than 1×10¹⁸ cm⁻³.

According to an embodiment, the process further includes forming sidewall spacers on opposite sides of the hard mask, and forming second doped regions of the second conductivity type on a bottom surface of the base regions. The second doped regions are adjacent to the first doped regions. In an embodiment, forming the second doped regions further includes conducting a vertical ion implantation of the base regions to implant second type dopants of the second conductivity type. In an embodiment, a dopant concentration of the second type dopants is more than 1×10¹⁹ cm⁻³ and less than 1×10²¹ cm⁻³.

According to an embodiment, the process further includes forming source regions of the first conductivity type above and in contact with the base regions, and selectively removing the hard mask and sidewall spacers.

According to an embodiment, the process further includes forming a gate oxide above the top portion of the JFET region, and forming a gate electrode above the gate oxide.

According to an embodiment, the process further includes forming an interlevel dielectric layer above the gate electrode and the gate oxide, forming a top electrode above the source regions, and forming a bottom electrode on a bottom surface of the semiconductor substrate.

### EXAMPLES

Example 1. A method of forming a semiconductor structure, comprising:
forming a semiconductor substrate of a first conductivity type, the semiconductor substrate including a silicon carbide substrate;
forming a drift layer of the first conductivity type above an upper surface of the semiconductor substrate;
forming a junction field-effect transistor (JFET) region of the first conductivity type above the drift layer;
forming base regions of a second conductivity type on opposite sides of a top portion of the JFET region, each base region being formed above and in contact with a bottom portion of the JFET region, wherein the second conductivity type is opposite to the first conductivity type;
forming a hard mask above the top portion of the JFET region located between the base regions; and
forming first doped regions of the first conductivity type within the JFET region, each first doped region being positioned at an interface between the base regions and the JFET region, the first doped regions extending into the JFET region such that a width of the top portion of the JFET region is reduced by the first doped regions.

Example 2. The method according to Example 1, wherein forming the first doped regions further comprises:
conducting a tilted ion implantation on the JFET region to implant first type dopants of the first conductivity type.

Example 3. The method according to Example 2, wherein the first type dopants include nitrogen.

Example 4. The method according to Example 2, wherein a dopant concentration of the first type dopants is more than 1×10¹⁵ cm⁻³ and less than 1×10¹⁸ cm⁻³.

Example 5. The method according to Example 1, further comprising:
forming sidewall spacers on opposite sides of the hard mask; and
forming second doped regions of the second conductivity type on a bottom surface of the base regions, the second doped regions being adjacent to the first doped regions.

Example 6. The method according to Example 5, wherein forming the second doped regions further comprises:
conducting a vertical ion implantation of the base regions to implant second type dopants of the second conductivity type.

Example 7. The method according to Example 6, wherein a dopant concentration of the second type dopants is more than 1×10¹⁹ cm⁻³ and less than 1×10²¹ cm⁻³.

Example 8. The method according to any of the preceding Examples, further comprising:
forming source regions of the first conductivity type above and in contact with the base regions; and
selectively removing the hard mask and sidewall spacers.

Example 9. The method according to any of the preceding Examples, further comprising:
forming a gate oxide above the top portion of the JFET region; and
forming a gate electrode above the gate oxide.

Example 10. The method according to any of the preceding Examples, further comprising:
forming an interlevel dielectric layer above the gate electrode and the gate oxide;
forming a top electrode above the source regions; and
forming a bottom electrode on a bottom surface of the semiconductor substrate.

Example 11. A method of forming a semiconductor structure, comprising:
forming a semiconductor substrate of a first conductivity type, the semiconductor substrate including a silicon carbide substrate;
forming a drift layer of the first conductivity type above an upper surface of the semiconductor substrate;
forming a junction field-effect transistor (JFET) region of the first conductivity type above the drift layer;
forming base regions of a second conductivity type on opposite sides of a top portion of the JFET region, each base region being formed above and in contact with a bottom portion of the JFET region, wherein the second conductivity type is opposite to the first conductivity type;
forming a hard mask above the top portion of the JFET region located between the base regions; and
conducting a localized tilted ion implantation on the JFET region to implant nitrogen ions, wherein the localized implantation forms first doped regions of the first conductivity type within the JFET region, the first doped regions being formed at an interface between the base regions and the JFET region, the first doped regions extending into the JFET region such that a width of the top portion of the JFET region is reduced by the first doped regions.

Example 12. The method according to Example 11, wherein a nitrogen concentration is more than 1×10¹⁵ cm⁻³ and less than 1×10¹⁸ cm⁻³.

Example 13. The method according to Example 11, further comprising:
forming sidewall spacers on opposite sides of the hard mask; and
forming second doped regions of the second conductivity type on a bottom surface of the base regions, the second doped regions being adjacent to the first doped regions.

Example 14. The method according to Example 13, wherein forming the second doped regions further comprises:
conducting a vertical ion implantation on the base regions to implant dopants of the second conductivity type.

Example 15. The method according to Example 14, wherein a dopant concentration of the second doped regions is more than 1×10¹⁹ cm⁻³ and less than 1×10²¹ cm⁻³.

Example 16. The method according to Example 13, further comprising:
forming source regions of the first conductivity type above and in contact with the base regions; and
selectively removing the hard mask and sidewall spacers.

Example 17. The method according to any of the preceding Examples, further comprising:
forming a gate oxide on the top portion of the JFET region; and
forming a gate electrode above the gate oxide.

Example 18. The method according to any of the preceding Examples, further comprising:
forming an interlevel dielectric layer above the gate electrode and the gate oxide;
forming a top electrode above the source regions; and
forming a bottom electrode on a bottom surface of the semiconductor substrate.

Example 19. A semiconductor structure comprising:
a semiconductor substrate of a first conductivity type, the semiconductor substrate including a silicon carbide substrate;
a drift layer of the first conductivity type disposed above an upper surface of the semiconductor substrate;
a JFET region including a top portion and a bottom portion, the JFET region being disposed above the drift layer;
a pair of base regions disposed on opposite sides of the top portion of the JFET region;
a pair of first doped regions located at an interface between the base regions and the JFET region, the first doped regions extending into the top portion of the JFET region such that width of the top portion of the JFET region is reduced by the first doped region; and
a pair of second doped regions located on a bottom portion of the base regions adjacent to the first doped regions.

Example 20. The semiconductor structure according to Example 1, further comprising:
a pair of source regions located above and in contact with the base regions;
a gate oxide located above the top portion of the JFET region;
a gate electrode located above the gate oxide;
an interlevel dielectric layer disposed above the gate electrode and the gate oxide;
a top electrode located above and in contact with the pair of source regions; and
a bottom electrode located on a bottom surface of the semiconductor substrate.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a semiconductor structure, comprising:
forming a semiconductor substrate of a first conductivity type, the semiconductor substrate including a silicon carbide substrate;
forming a drift layer of the first conductivity type above an upper surface of the semiconductor substrate;
forming a junction field-effect transistor (JFET) region of the first conductivity type above the drift layer;
forming base regions of a second conductivity type on opposite sides of a top portion of the JFET region, each base region being formed above and in contact with a bottom portion of the JFET region, wherein the second conductivity type is opposite to the first conductivity type;
forming a hard mask above the top portion of the JFET region located between the base regions; and
forming first doped regions of the first conductivity type within the JFET region, each first doped region being positioned at an interface between the base regions and the JFET region, the first doped regions extending into the JFET region such that a width of the top portion of the JFET region is reduced by the first doped regions.

2. The method according to claim 1, wherein forming the first doped regions further comprises:
conducting a tilted ion implantation on the JFET region to implant first type dopants of the first conductivity type.

3. The method according to claim 2, wherein the first type dopants include nitrogen.

4. The method according to claim 2, wherein a dopant concentration of the first type dopants is more than 1×10¹⁵ cm⁻³ and less than 1×10¹⁸ cm⁻³.

5. The method according to claim 1, further comprising:
forming sidewall spacers on opposite sides of the hard mask; and
forming second doped regions of the second conductivity type on a bottom surface of the base regions, the second doped regions being adjacent to the first doped regions.

6. The method according to claim 5, wherein forming the second doped regions further comprises:
conducting a vertical ion implantation of the base regions to implant second type dopants of the second conductivity type.

7. The method according to claim 6, wherein a dopant concentration of the second type dopants is more than 1×10¹⁹ cm⁻³ and less than 1×10²¹ cm⁻³.

8. The method according to claim 5, further comprising:
forming source regions of the first conductivity type above and in contact with the base regions; and
selectively removing the hard mask and sidewall spacers.

9. The method according to claim 8, further comprising:
forming a gate oxide above the top portion of the JFET region; and
forming a gate electrode above the gate oxide.

10. The method according to claim 9, further comprising:
forming an interlevel dielectric layer above the gate electrode and the gate oxide;
forming a top electrode above the source regions; and
forming a bottom electrode on a bottom surface of the semiconductor substrate.

11. A method of forming a semiconductor structure, comprising:
forming a semiconductor substrate of a first conductivity type, the semiconductor substrate including a silicon carbide substrate;
forming a drift layer of the first conductivity type above an upper surface of the semiconductor substrate;
forming a junction field-effect transistor (JFET) region of the first conductivity type above the drift layer;
forming base regions of a second conductivity type on opposite sides of a top portion of the JFET region, each base region being formed above and in contact with a bottom portion of the JFET region, wherein the second conductivity type is opposite to the first conductivity type;
forming a hard mask above the top portion of the JFET region located between the base regions; and
conducting a localized tilted ion implantation on the JFET region to implant nitrogen ions, wherein the localized implantation forms first doped regions of the first conductivity type within the JFET region, the first doped regions being formed at an interface between the base regions and the JFET region, the first doped regions extending into the JFET region such that a width of the top portion of the JFET region is reduced by the first doped regions.

12. The method according to claim 11, wherein a nitrogen concentration is more than 1×10¹⁵ cm⁻³ and less than 1×10¹⁸ cm⁻³.

13. The method according to claim 11, further comprising:
forming sidewall spacers on opposite sides of the hard mask; and
forming second doped regions of the second conductivity type on a bottom surface of the base regions, the second doped regions being adjacent to the first doped regions.

14. The method according to claim 13, wherein forming the second doped regions further comprises:
conducting a vertical ion implantation on the base regions to implant dopants of the second conductivity type.

15. The method according to claim 14, wherein a dopant concentration of the second doped regions is more than 1×10¹⁹ cm⁻³ and less than 1×10²¹ cm⁻³.

16. The method according to claim 13, further comprising:
forming source regions of the first conductivity type above and in contact with the base regions; and
selectively removing the hard mask and sidewall spacers.

17. The method according to claim 16, further comprising:
forming a gate oxide on the top portion of the JFET region; and
forming a gate electrode above the gate oxide.

18. The method according to claim 17, further comprising:
forming an interlevel dielectric layer above the gate electrode and the gate oxide;
forming a top electrode above the source regions; and
forming a bottom electrode on a bottom surface of the semiconductor substrate.

19. A semiconductor structure comprising:
a semiconductor substrate of a first conductivity type, the semiconductor substrate including a silicon carbide substrate;
a drift layer of the first conductivity type disposed above an upper surface of the semiconductor substrate;
a JFET region including a top portion and a bottom portion, the JFET region being disposed above the drift layer;
a pair of base regions disposed on opposite sides of the top portion of the JFET region;
a pair of first doped regions located at an interface between the pair of base regions and the JFET region, the pair of first doped regions extending into the top portion of the JFET region such that width of the top portion of the JFET region is reduced by the pair of first doped regions; and
a pair of second doped regions located on a bottom portion of the pair of base regions adjacent to the pair of first doped regions.

20. The semiconductor structure according to claim 19, further comprising:
a pair of source regions located above and in contact with the pair of base regions;
a gate oxide located above the top portion of the JFET region;
a gate electrode located above the gate oxide;
an interlevel dielectric layer disposed above the gate electrode and the gate oxide;
a top electrode located above and in contact with the pair of source regions; and
a bottom electrode located on a bottom surface of the semiconductor substrate.
